(19) United States
(12) Patent Application Publication
(10) Pub. No.: US 2025/0105596 A1
(43) Pub. Date: Mar. 27, 2025

(54) COHERENT RING VERTICAL CAVITY SURFACE EMITTING LASER

(71) Applicant: Dallas Quantum Devices, Allen, TX (US)

(72) Inventors: Luke Allen Graham, Allen, TX (US); Jimmy Alan Tatum, Celina, TX (US); James Kenneth Guenter, Princeton, TX (US); Pritha Khurana, Frisco, TX (US)

(21) Appl. No.: 18/424,601

(22) Filed: Jan. 26, 2024

Related U.S. Application Data
(60) Provisional application No. 63/585,453, filed on Sep. 26, 2023.

(51) Int. Cl. H01S 5/42; H01S 5/183

(52) U.S. Cl. CPC H01S 5/423; H01S 5/18305; H01S 5/18311; H01S 5/18377; H01S 5/18394

(57) ABSTRACT

Disclosed examples include Coherent Ring Vertical Cavity Surface Emitting Lasers (CR-VCSEL). Examples includes Vertical Cavity Surface Emitting Lasers with a containing a Coherent Ring Vertical Cavity Surface Emitting Laser stack (CR-VCSEL stack) consisting of a first mirror layer, an active layer, an emission aperture, and a second mirror layer, under a top metal layer within a closed ring. The CR-VCSEL has a closed ring structure. The emission aperture width of the closed ring is such that the closed ring supports a single transverse optical mode, it but supports multiple circumferential optical modes around the ring within the closed ring geometry. The closed ring may have a length of from microns to millimeters. The transverse width of the closed ring and length of the closed ring may be tailored to control the CR-VCSEL power output, degree of coherence, and laser beam emission pattern.

### CROSS-REFERENCE TO RELATED APPLICATIONS

This application claims the benefit of priority under 35 U.S.C. § 119(e) of U.S. Provisional Application No. 63/585,453, attorney docket DQD003, filed Oct. 12, 2023 and incorporated herein by reference in its entirety.

### TECHNICAL FIELD

This disclosure relates to the field of microelectronic devices. More particularly, but not exclusively, this disclosure relates to Vertical Cavity Surface Emitting Lasers (VCSEL).

### BACKGROUND

Vertical Cavity Surface Emitting Lasers are being continually improved to reliably operate with higher performance. Fabricating Vertical Cavity Surface Emitting lasers that have increasingly higher performance presents diverse challenges.

### SUMMARY

This summary is provided to introduce a brief overview of disclosed concepts in a simplified form that are further described below in the detailed description including the drawings provided. This summary is not intended to limit the scope of the disclosure or the claims. Disclosed examples include Coherent Ring Vertical Cavity Surface Emitting Lasers (CR-VCSEL). Examples includes vertical cavity surface emitting lasers with a coherent ring configuration.

### BRIEF DESCRIPTION OF THE VIEWS OF THE DRAWINGS

FIG. 1A through FIG. 1G are a top-down view and cross sections of an example Coherent Ring Vertical Cavity Surface Emitting Laser in various stages of formation.

FIG. 2 is a perspective view of an example Coherent Ring Vertical Cavity Surface Emitting Laser in a back emitting configuration.

FIG. 3 is a perspective view of an example Coherent Ring Vertical Cavity Surface Emitting Laser in a top emitting ridge configuration.

FIG. 4 is a perspective view of an example Coherent Ring Vertical Cavity Surface Emitting Laser in a buried index guide configuration.

FIG. 5 is a top-down view an example Coherent Ring Vertical Cavity Surface Emitting Laser in a 1-D array configuration.

FIG. 6 is a top-down view of an example Coherent Ring Vertical Cavity Surface Emitting Laser in a 2-D array configuration.

FIG. 7 is a top-down view of an example Coherent Ring Vertical Cavity Surface Emitting Laser in a nested array configuration.

FIG. 8 is a top-down view of an example Coherent Ring Vertical Cavity Surface Emitting Laser in a clipped corner configuration.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events unless otherwise stated. Furthermore, not all illustrated acts or events are required to implement a methodology in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure may be illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to various examples.

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate. Moreover, the term “approximately,” as used herein, may refer to ±5% to ±10% variations of the recited values in some cases. In other cases, the term “approximately” may refer to ±10% to ±20% variations of the recited values.

A vertical cavity surface-emitting laser (VCSEL) is a class of semiconductor laser which is used in applications such as precision magnetometers, atomic clocks, quantum computing, Raman spectroscopy, frequency doubling, and optical communications among other devices. VCSEL's are being continually improved to reliably operate with higher performance and smaller feature sizes. A VCSEL typically consists of two parallel reflectors with a thin active layer between them with a round current/emission aperture diameter on the order of 2-5 um and are typically 3-20 um² with a single frequency maximum power output of 0.5-3 mW. Larger diameter VCSEL lasers with greater capability generally do not support single mode/frequency operation. The disclosed CR-VCSEL geometry allows a single frequency with a much greater area (1000-20,000 um²) with optical power up to 1 W or more. The disclosed CR-VCSEL may be realized with similar processing techniques to current emission aperture VCSEL's.

For the purpose of the disclosure, a closed ring is herein defined as any closed surface with both inner and outer boundaries, and a width with a closed surface geometry. One example of such a closed ring feature is an annulus, a continuous circular feature with inner and outer boundaries separated by a finite width. Analogous examples include oblong, rectangular, hexagonal, and similar geometric shapes. The direction locally perpendicular to the inner and outer boundaries is defined herein as transverse, and the direction locally parallel to the inner and outer boundaries is defined as circumferential, regardless of ring shape.

For the purposes of the disclosure, a Coherent Ring Vertical Cavity Surface Emitting Laser stack (CR-VCSEL stack) is defined as a stack within a closed ring including a first mirror layer, an active layer, an emission aperture, and a second mirror layer, under a top metal layer.

For the purposes of the disclosure, a Single Optical Mode is defined as operating in substantially a single optical mode of the transverse closed ring waveguide. Additionally, the closed ring structure may support multiple circumferential modes that may lase simultaneously. These modes taken together form supermodes of the CR VCSEL and display substantially coherent behavior.

The CR-VCSEL has a closed ring structure. The emission aperture width of the closed ring is such that the closed ring supports a single transverse optical mode, it but supports multiple circumferential optical modes around the ring within the closed ring geometry. The closed ring may have a length from microns to millimeters. The transverse width of the closed ring and length of the closed ring may be tailored to control the CR-VCSEL power output, degree of coherence, and laser beam emission pattern.

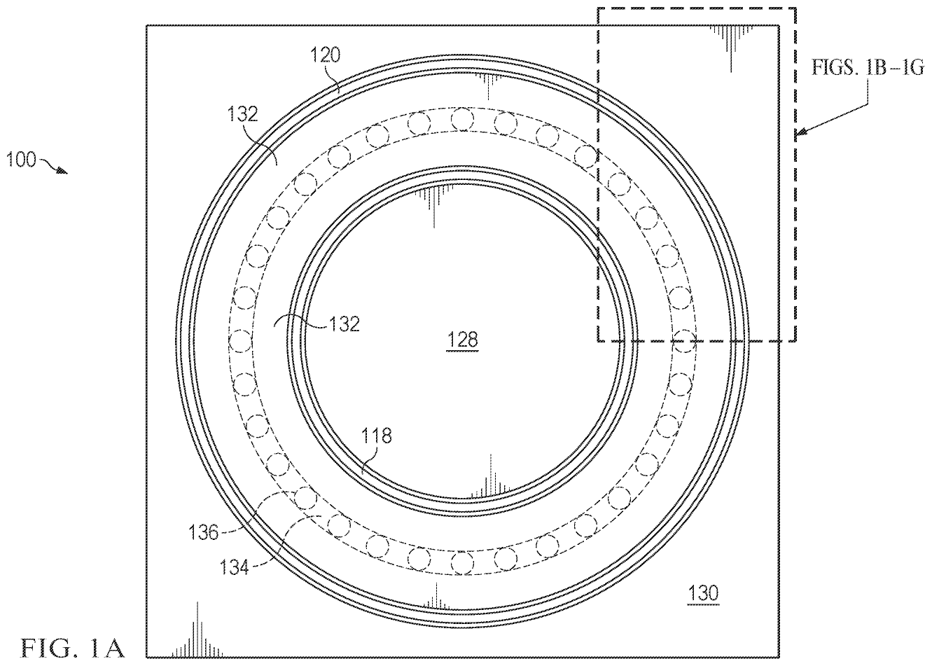

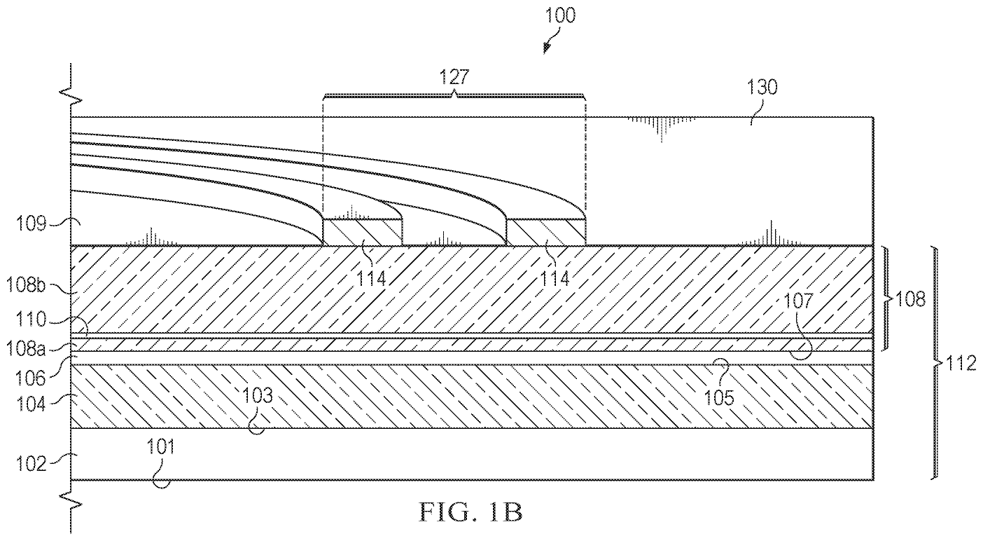

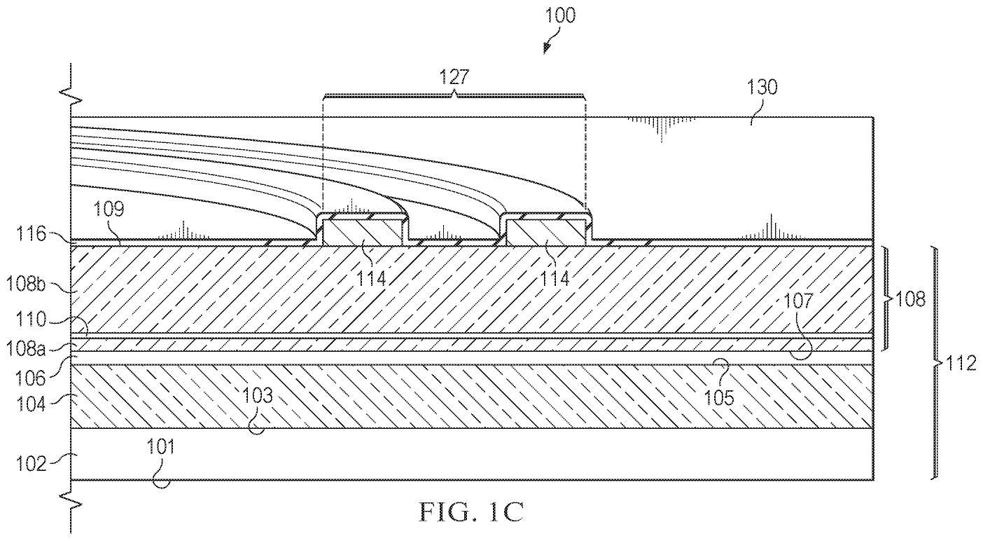

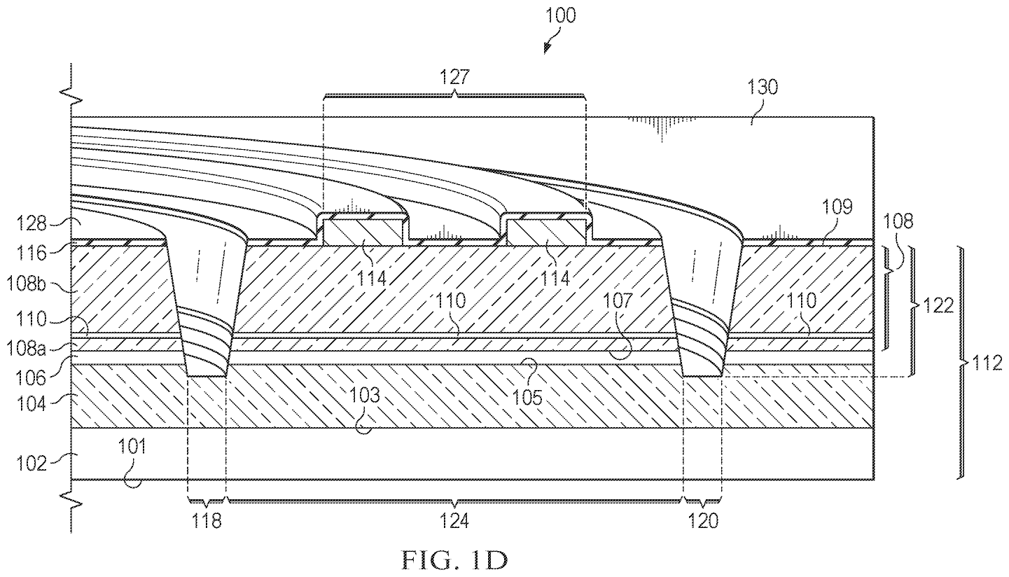

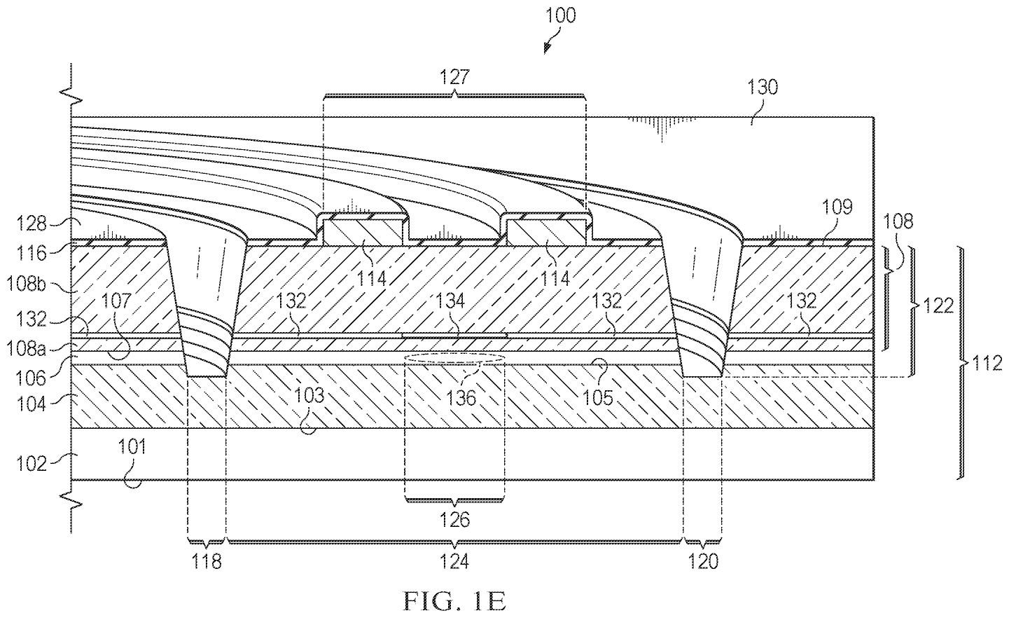

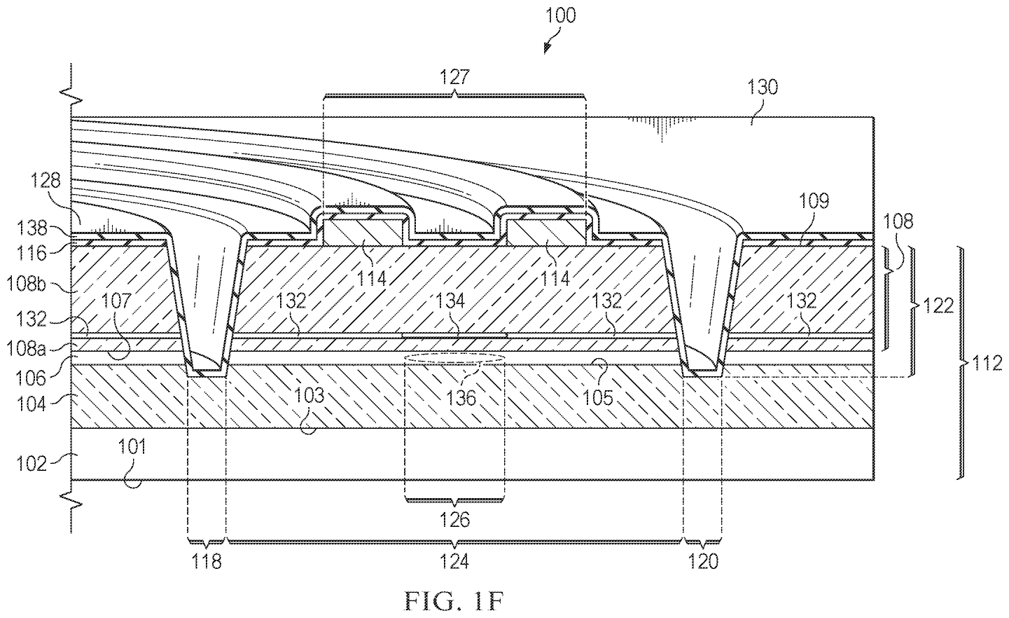

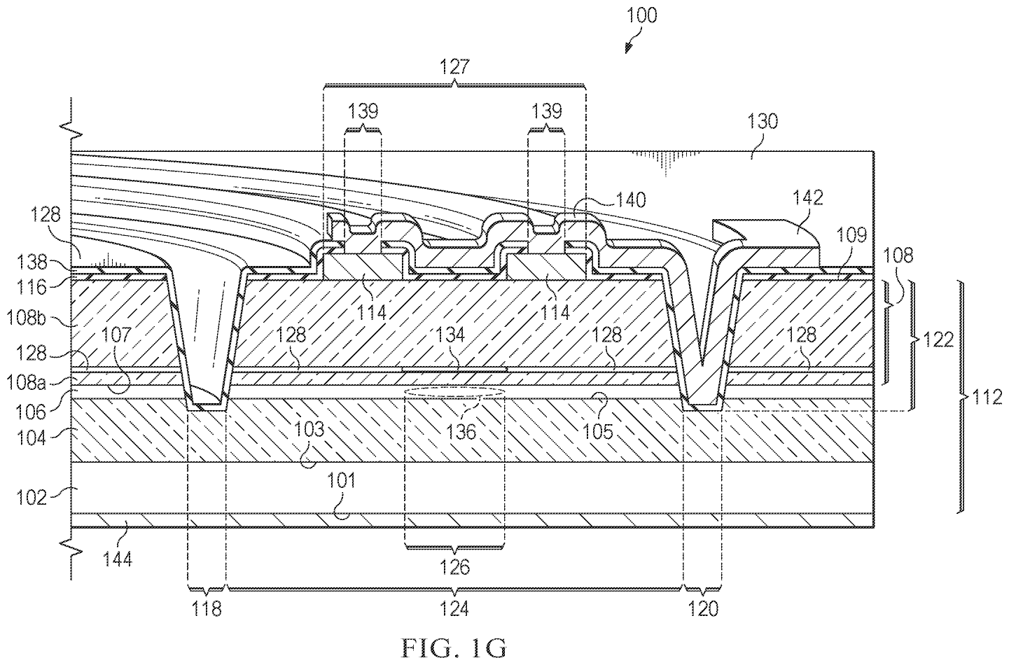

FIG. 1A is a top-down representation of an example oxide trench CR-VCSEL 100. The oxide trench CR-VCSEL 100 shown is formed using a process described in FIGS. 1B-1G. The oxide trench CR-VCSEL 100 of FIG. 1A is bounded by an inner trench 118 in a closed ring configuration and an outer trench 120 in a closed ring configuration. An oxidation process, referred to in FIG. 1E, forms oxidized regions 132 of an oxidation layer 110, referred to in FIG. 1B, from the inner trench 118 and the outer trench 120 toward a mid-point between the inner trench 118 and the outer trench 120. A region of the oxidation layer 110 which remains unoxidized after the oxidation process is herein referred to as an emission aperture 134. During operation of the oxide trench CR-VCSEL 100, optical modes 136 form in the active layer 106, referred to in FIG. 1B, under the emission aperture 134. The optical modes 136 under the emission aperture 134 are in physical proximity to each other such that the electric field of the plurality of optical modes 136 influence one another with the plurality of optical modes 136 locking together to form a single “supermode” at a single wavelength. While multiple optical modes 136 form circumferentially around the closed ring of the oxide trench CR-VCSEL 100 between the inner trench 118 and the outer trench 120, only a single optical mode 136 is formed in the transverse direction between the inner trench 118 and the outer trench 120. Additional layers of the oxide trench CR-VCSEL 100 such as a top metal layer 114, referred to in FIG. 1B, a first passivation layer 116, referred to in FIG. 1C, a second passivation layer 138, referred to in FIG. 1F, a top metal interconnect 140, referred to in FIG. 1G, and top metal bond pad 142, referred to in FIG. 1G are not shown for clarity.

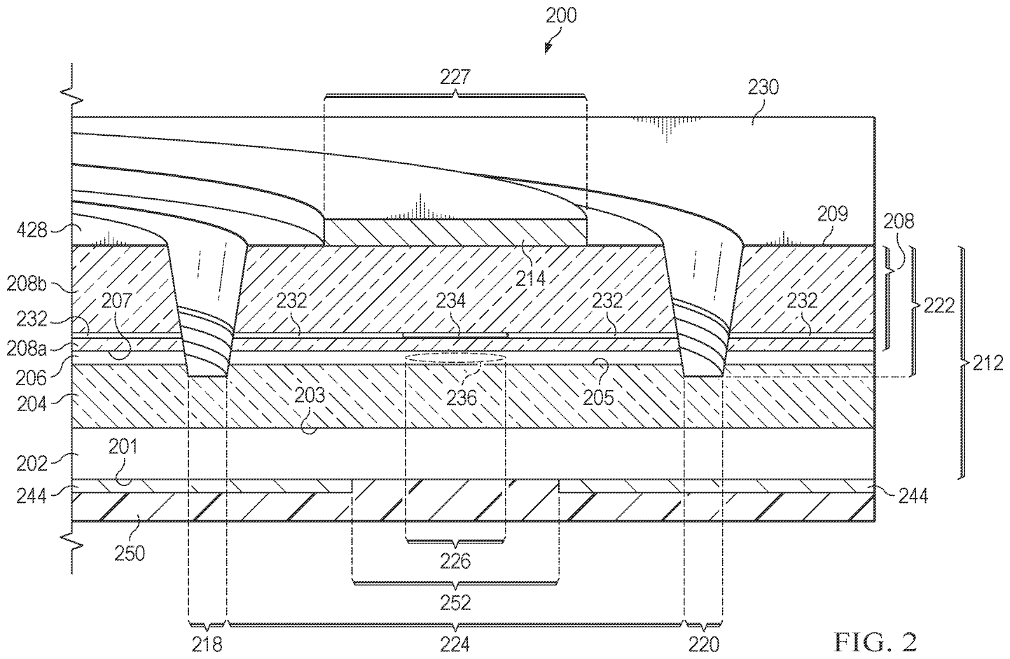

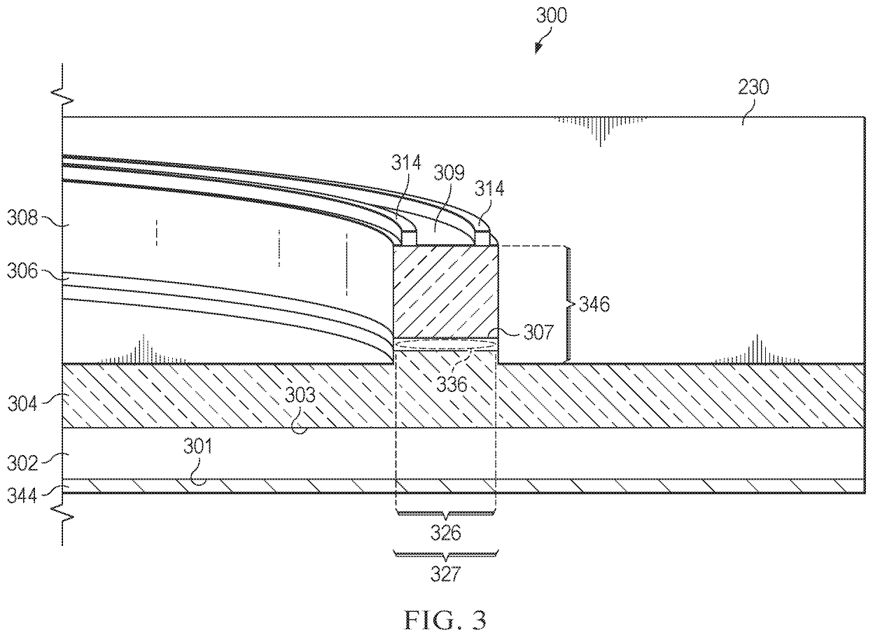

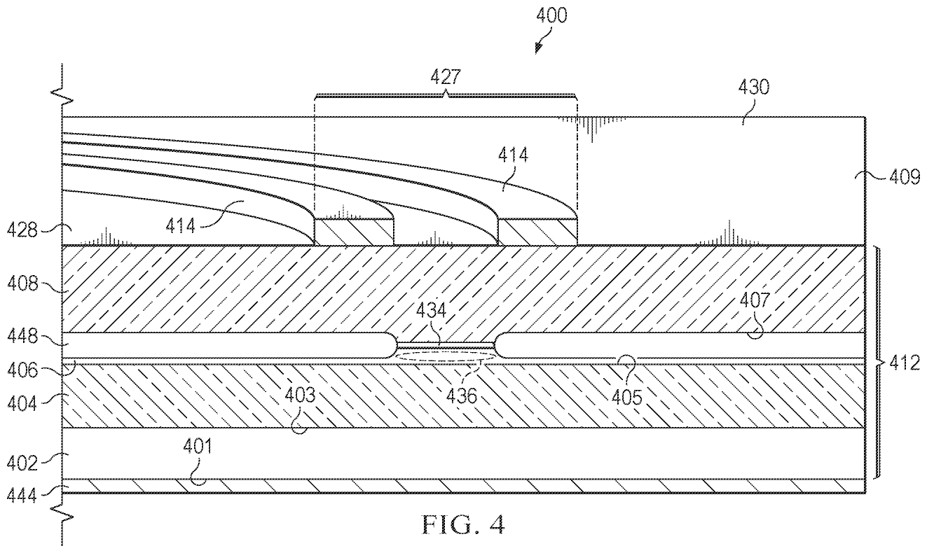

FIG. 1B through FIG. 1G are representative figures describing an example process to form the oxide trench CR-VCSEL 100 to which the principles of the disclosure may be beneficially applied. These figures show cross sections of the oxide trench CR-VCSEL 100 in successive stages of an example method of formation. Other CR-VCSEL implementations similar to the oxide trench CR-VCSEL 100 include a back emitting oxide trench CR-VCSEL 200 (FIG. 2), a top emitting ridge CR-VCSEL 300 (FIG. 3), and a buried index guide CR-VCSEL 400 (FIG. 4). Other methods of forming VCSEL's which may be applied to forming a CR-VCSEL are within the scope of this disclosure.

FIG. 1B shows the oxide trench CR-VCSEL 100 after the formation on a substrate 102 of a bottom n-type distributed Bragg reflector (n-type DBR) 104, herein referred to as a first mirror layer 104, with a first mirror layer bottom surface 103 and a first mirror layer top surface 105, an active layer 106 containing a quantum well structure, a top p-type distributed Bragg reflector (p-type DBR) 108, herein referred to as a second mirror layer 108, the second mirror layer 108 containing a second mirror layer lower portion 108a under an oxidation layer 110, and a second mirror layer upper portion 108b on the oxidation layer 110. The second mirror layer 108 has a second mirror layer top surface 109 and a second mirror layer bottom surface 107. The oxidation layer 110 may be AlGaAs, AlAs, or similar material with a different refractive index than the first mirror layer 104 or the second mirror layer 108. The first mirror layer 104 is formed of alternating layers of two materials of differing refractive index such as Al_{0.9}Ga_{0.1}As and Al_{0.3}Ga_{0.7}As by way of example. A n-type dopant such as silicon may be used at a concentration of 3×10¹⁸ cm⁻³ by way of example in the first mirror layer 104 which is n-type doped. The second mirror layer 108 is formed of alternating layers of two materials of differing refractive index such as Al_{0.9}Ga_{0.1}As and Al_{0.3}Ga_{0.7}As by way of example. The second mirror layer 108 may be doped with carbon or similar dopant material with a dopant concentration of approximately 3×10¹⁸ cm⁻³ by way of example resulting in an overall p-type doped second mirror layer 108.

FIG. 1B shows the oxide trench CR-VCSEL 100 after a top metal layer 114 has been formed. The top metal layer 114 is in electrical contact to the second mirror layer 108. The top metal layer 114 may be gold, aluminum, copper, or another suitable conductor. To form the top metal layer 114, a layer of metal (not specifically shown) is formed on the second mirror layer 108. A photolithographic step and a plasma etch step are used to form the top metal layer 114. In the example shown in FIG. 1B, the top metal layer 114 consists of two closed rings on opposite sides of the emission aperture 134, referred to in FIG. 1E. In some embodiments (not specifically shown) the inner and outer metal regions may be connected with one or more metal bridges that cross over the emission aperture. Other configurations of the top metal layer 114 are within the scope of this disclosure.

FIG. 1C shows the oxide trench CR-VCSEL 100 after a first passivation layer 116 is formed over the second mirror layer 108 and the on the top metal layer 114. The first passivation layer 116 is a layer of a material such as silicon oxynitride, silicon nitride, or another suitable dielectric. The first passivation layer 116 is chosen from materials which may transmit the oscillation wavelength generated by the oxide trench CR-VCSEL 100. The refractive index of the first passivation layer 116 may be less than the refractive index of the second mirror layer 108. The thickness of the first passivation layer 116 may be an odd multiple of the quarter wavelength of the emitted laser light (λ/4). The first passivation layer 116 may function both as a passivation layer to protect the underlying layers from damage and to focus the emitted laser light from the underlying optical modes 136, referred to in FIG. 1E. A CR-VCSEL stack 127 referred to in FIG. 1B-FIG. 1G refers to a region wherein the active elements of the oxide trench CR-VCSEL 100 are formed. The CR-VCSEL stack 127 is a closed ring containing a portion of the first mirror layer 104, the active layer, the emission aperture 134, the optical mode 136, and the second mirror layer 108 under the top metal layer 114.

FIG. 1D shows the oxide trench CR-VCSEL 100 after a photolithographic pattern step and a plasma trench etch (neither specifically shown) have formed an inner trench 118 and an outer trench 120. The inner trench 118 and the outer trench 120 may extend from the second mirror layer top surface 109 of the second mirror layer 108, intersecting the oxidation layer 110, the active layer 106, and may terminate in the first mirror layer 104. The inner trench 118 and the outer trench 120 are closed ring features as shown in FIG. 1A. The formation of the inner trench 118 and the outer trench 120 result in the formation of a mesa 124, which is also a closed ring, between the inner trench 118 and the outer trench 120.

FIG. 1E shows the oxide trench CR-VCSEL 100 after an oxidation step (not specifically shown) has selectively oxidized a portion of the oxidation layer 110 referred to in FIG. 1B-FIG. 1D. Once oxidized, the portion of the oxidation layer 110 which is oxidized is referred to as an oxidized region 132, and the portion which remains unoxidized between the inner trench 118 and the outer trench 120 is referred to as the emission aperture 134. The oxidation layer 110 which may be a material such as p-type AlₓGa_{y}As (x>0.9, y,0.1), AlAs, or similar material which has a higher aluminum content than the second mirror layer 108 or the first mirror layer 104, which may be AlₓGa_{y}As (x=0.7-0.9, y=0.1-0.3. The higher aluminum content of the oxidation layer 110 results in a higher oxidation rate of the oxidation layer 110 compared to the second mirror layer 108 and the first mirror layer 104. The oxidation step proceeds from both the inner trench 118 and the outer trench 120 towards the center of the mesa 124 forming the oxidized region 132 with minimal oxidation of the exposed sidewalls of the second mirror layer 108 and the first mirror layer 104. The oxidation of the oxidation layer 110 also proceeds from the inner trench 118 and the outer trench 120 away from the mesa 124, into the inner inactive region 128 and the outer inactive region 130 respectively, but the oxidation outside the mesa 124 is not a functional portion of the oxide trench CR-VCSEL 100.

The formation of the oxidized region 132 is a timed or optically monitored oxidation which controls the width of the resulting emission aperture 134, the emission aperture 134 maintaining the elemental composition shown in FIG. 1C as the oxidation layer 110. The emission aperture 134 is a closed ring within the mesa 124 and between the inner trench 118 and the outer trench 120. During operation of the oxide trench CR-VCSEL 100, optical modes 136 are formed in the active layer 106 of the CR-VCSEL stack 127 under the emission aperture 134 with multiple optical modes present in the closed ring of the CR-VCSEL stack 127, the top-down view of the closed ring as shown in FIG. 1A. The emission aperture width 126 in the transverse direction between the inner trench 118 and outer trench 120 allows the formation of a single optical mode 136 between the inner trench 118 and the outer trench 120. The multiple optical modes 136 in the CR-VCSEL stack 127 closed ring become a “supermode” which emits at a single wavelength from the multiple optical modes 136.

Referring to FIG. 1F, a second passivation layer 138 may be formed on the first passivation layer 116, the inner trench 118, and the outer trench 120 of the oxide trench CR-VCSEL 100. The second passivation layer 138 may be a layer of a titanium dioxide, silicon oxynitride, silicon nitride, or other material which is transparent to the CR-VCSEL emitted laser light. The thickness of the second passivation layer 138 may be such that the second passivation layer 138 thickness is an odd multiple of the quarter wavelength of the emission (λ/4). The refractive index of the second passivation layer 138 may be higher than the refractive index of the first passivation layer 116. The second passivation layer 138 is optically clear to the emitted laser light of the oxide trench CR-VCSEL 100 and provides a protective layer over the oxide trench CR-VCSEL 100. Alternatively, the first passivation layer 116 may be removed over the emission aperture and the second passivation layer 138 may have a thickness that is an even multiple of the wavelength of the emission (not specifically shown).

FIG. 1G shows the oxide trench CR-VCSEL 100 after a top metal interconnect 140 is formed which electrically connects the top metal layer 114 with a top metal bond pad 142. To form the top metal interconnect 140, a photolithographic pattern step and a plasma etch step (neither specifically shown) are used to remove the second passivation layer 138 and the first passivation layer 116 and form a passivation via 139 in the open areas of the photolithographic pattern which expose the underlying top metal layer 114. The example oxide trench CR-VCSEL 100 of FIG. 1G shows the passivation vias 139 for each portion of the top metal layer 114 by way of example. After the formation of the passivation vias 139, a metal layer (not specifically shown) is formed over the second passivation layer 138 and the exposed regions of the top metal layer 114. An additional photolithographic pattern step and etch step (neither specifically shown) form the top metal interconnect 140 in areas defined by the photolithographic pattern, and remove the metal layer from other areas over the second passivation layer 138. The top metal interconnect 140 may be gold, aluminum, copper, or other appropriate metal conductor. The photolithographic pattern which defines the top metal interconnect 140 also defines a top metal bond pad 142 which is formed concurrently and is in electrical contact with the top metal layer 114, the top metal interconnect 140, and a second terminal (not specifically shown). For clarity, in FIG. 1G, a single top metal interconnect 140 is shown. Multiple top metal interconnects 140 may be placed around the closed ring of the oxide trench CR-VCSEL 100 to contact the top metal layer 114 in multiple locations with one or more top metal bond pads 142. In the example device of FIG. 1G, a bottom metal layer 144 is formed on the back side of the substrate 102. The bottom metal layer 144 allows electrical contact through the substrate 102 and the first mirror layer 104 to the active layer 106. The bottom metal layer 144 may be gold, aluminum, copper, or any other suitable conductor. While the bottom metal layer 144 in the example device is a bottom of the substrate 102, the bottom metal layer 144 may be placed in other positions to electrically contact the active layer 106 and a first terminal (not specifically shown).

Referring to FIG. 2, an alternate embodiment of a CR-VCSEL is shown herein referred to as a back emitting oxide trench CR-VCSEL 200. For clarity, layers corresponding to the top metal interconnect 140, the second passivation layer 138 and the first passivation layer 116 have been removed. The back emitting oxide trench CR-VCSEL 200 is formed in a manner similar to the oxide trench CR-VCSEL 100 except in the formation of a top metal layer 214, a bottom metal layer 244 and in formation the of an additional layer, an antireflective coating 250.

A substrate 202, a first mirror layer 204, an active layer 206, a second mirror layer 208, and the oxidation layer (not specifically shown) are all formed in a manner similar to the corresponding layers discussed in FIG. 1B. While the top metal layer 114 of FIG. 1B is formed with two closed rings on opposite sides of the emission aperture with the laser emission passing between the two closed rings of the top metal layer 114 regions, the top metal layer 214 of FIG. 2 is formed as a single closed ring over the emission aperture 234. In the back emitting oxide trench CR-VCSEL 200, the top metal layer 214 serves both as an electrical contact to the second mirror layer 208 and may function as a reflector for the optical mode 136 to reflect the laser light through the bottom surface of the substrate 102 where the laser light is emitted.

The inner trench 218 and the outer trench 220 are formed in a manner similar to formation of the inner trench 118 and the outer trench 120 discussed FIG. 1D.

The formation of the oxidized region 232, the emission aperture 234 and the optical mode 236, are analogous to the formation of the oxidized region 132, the emission aperture 134 and the optical mode 136 discussed in FIG. 1E.

While the bottom metal layer 144 in the oxide trench CR-VCSEL 100 of FIG. 1G covers the substrate bottom surface 101 of the substrate 102, the bottom metal layer 244 of the back emitting oxide trench CR-VCSEL 200 has a bottom metal opening 252 which is a continuous closed ring and is free of metal between the inner trench 218 and the outer trench 220, under the emission aperture 234 and under the optical mode 236 to allow emission of the laser light from the optical mode 236 to exit the back emitting oxide trench CR-VCSEL 200 through the substrate 202. The bottom metal opening 252 is formed by forming a layer of metal on the bottom surface 201 of the substrate 202, followed by a photolithographic pattern step and an etch step (not specifically shown) with the etch step removing the metal layer in the region of the bottom metal opening 252 resulting formation of the bottom metal layer 244. Another alternative (not specifically shown) is for the bottom metal layer 244 to be deposited from the top of the structure after first etching to enable electrical contact to bottom mirror layer 203 or substrate 202. After the formation of the bottom metal layer 244, the antireflective coating 250 of a dielectric such as silicon oxynitride, silicon dioxide, or a combination thereof may be formed. The antireflective coating 250 may function to enhance transmission of the laser light and to service as a protective layer.

Referring to FIG. 3, another alternate embodiment of a CR-VCSEL is shown herein referred to as a top emitting ridge CR-VCSEL 300. Layers corresponding to the top metal interconnect 140, the second passivation layer 138 and the first passivation layer 116 of FIG. 1G have been removed for clarity in FIG. 3. The top emitting ridge CR-VCSEL 300 is formed in a manner similar to the oxide trench CR-VCSEL 100 with the exception of the composition of the starting CR-VCSEL stack 112, and in the formation of a top emitting ridge 346 which is formed in place of an inner trench 118 and an outer trench 120 of the oxide trench CR-VCSEL 100.

The substrate 302, first mirror layer 304, and active layer 206, are similar in composition and layer thicknesses to the substrate 102, first mirror layer 104, and active layer 106 referred to in FIG. 1B. Unlike the second mirror layer 108, referred to in FIG. 1B which consists of a second mirror layer lower portion 108a, an oxidation layer 110, and a second mirror layer upper portion 108b, the second mirror layer 308 of the top emitting ridge CR-VCSEL 300 is formed without an oxidation layer and consists only of alternating layers of Al_{0.90}Ga_{0.1}As and Al_{0.3}Ga_{0.7}As or similar materials suitable for the second mirror layer 308. The top metal 314 may be narrower than the top metal layer 114 of FIG. 1B due to the fact the top emitting ridge 346 top surface ring is narrower than the mesa 124 and top metal layer 114 of the oxide trench CR-VCSEL 100.

In the top emitting ridge CR-VCSEL 300 a top emitting ridge 346 is formed with a width similar to the width of the emission aperture 134 of FIG. 1E. In the oxide trench CR-VCSEL 100, the emission aperture 134 focuses the optical modes 136. In the top emitting ridge CR-VCSEL 300, the top emitting ridge 346 is formed with a width to allow the refractive index difference between the edges of the top emitting ridge 346 and the atmosphere adjacent to the top emitting ridge 346 to confine optical modes to a single optical mode in the transverse direction of the CR-VCSEL stack 327. A photolithographic step (not specifically shown) patterns a photoresist over the top of the top emitting ridge 346 and an angled implant (not specifically shown) is used to cause implant damage on the sidewalls of the top emitting ridge 346. The implant damaged sidewall and with the narrow width of the top emitting ridge 346 confine the optical mode 336 of the top emitting ridge CR-VCSEL 300.

Referring to FIG. 4, an alternate embodiment of a CR-VCSEL is shown herein referred to as a buried index guide CR-VCSEL 400. For clarity, layers corresponding to the top metal interconnect 140, the second passivation layer 138 and the first passivation layer 116 of FIG. 1G have been removed. The buried index guide CR-VCSEL 400 is another alternate formation method of an emission aperture 434 similar to the emission aperture 134 of the oxide trench CR-VCSEL 100.

The emission aperture 434 of a buried index guide CR-VCSEL 400 may be formed by various methods, the example buried index guide CR-VCSEL 400 using a buried tunnel junction structure. The substrate 402, first mirror layer 404, and active layer 406, are all formed in a manner similar to the substrate 102, the first mirror layer 104 and active layer 106 referred to in FIG. 1B. A tunnel junction layer (not specifically shown) is grown on the active layer 106. A photolithographic step defines an area for the emission aperture 434, and a plasma etch step removes the tunnel junction layer and the active layer 106 in open regions of the photolithographic pattern, the remaining tunnel junction layer herein referred to as the emission aperture 434 of the buried index guide CR-VCSEL 400. The formation of the emission aperture 434 is followed by regrowth of the second mirror layer 408. A lower doping of the regrown material forms a current blocking reverse bias diode junction region 448. The etched vertical step at the edges of the emission aperture 434 followed by regrowth of the second mirror layer 408 forms an index guide that confines the optical mode of the buried index guide CR-VCSEL 400.

In other related embodiments, an ion implantation may be added in the current blocking reverse bias diode junction region 448 to block current flow if the etched step emission aperture 434 does not incorporate a current blocking function on its own. Alternatively, in a lithographic VCSEL embodiment, the etched region of the emission aperture 434 is highly doped and has a large aluminum concentration discontinuity that blocks current when etched away and regrown with low doped low aluminum material in the second mirror layer 408 which forms the current blocking reverse bias diode junction region 448.

In all of these embodiments to form the buried index guide CR-VCSEL 400, a photolithographic pattern is used to form the area for the emission aperture 434 which is a closed ring. Optical modes 436 may form under the emission aperture 434 during device operation and as in other embodiments the width in the transverse direction allows formation of only a single optical mode. After the formation of the emission aperture 434 and the second mirror layer, a top metal 414 is formed. Additional layers have been removed for clarity, but are formed and correspond to the first passivation layer 116, the second passivation layer 138, the top metal interconnect 140, and the top metal bond pad 142 of FIG. 1B-FIG. 1G. The buried index CR-VCSEL has a CR-VCSEL stack 427 is a closed ring. Additional layers and surfaces include a second mirror layer top surface 409, a second mirror layer bottom surface 407, a first mirror layer top surface 405 a first mirror layer bottom surface 403 a bottom metal 444, and a bottom metal bottom surface 401. The buried index guide CR-VCSEL 400 may also be formed in a back emitting configuration similar to the back emitting oxide CR-VCSEL 200.

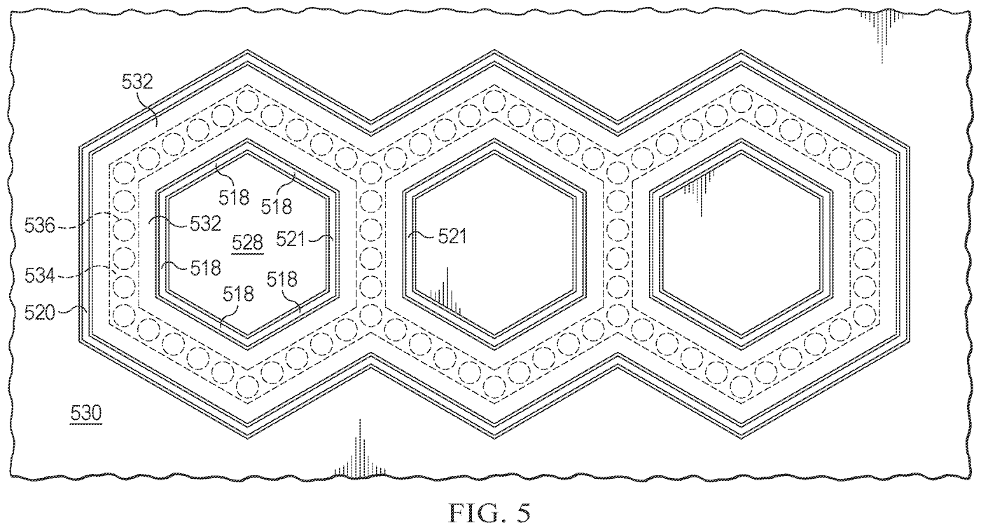

FIG. 5 is a top-down representation CR-VCSEL 1-D array 500. The CR-VCSEL 1-D array 500 of FIG. 5 is formed in a manner similar to the oxide trench CR-VCSEL 100 referred to in FIGS. 1B-1G, but could be formed in the configuration of a back emitting oxide trench CR-VCSEL 200, a top ridge emitting CR-VCSEL 300 or a buried index guide CR-VCSEL 400 by way of example. The CR-VCSEL 1-D array 500 shown in FIG. 5 consists of hexagons, but could be formed of any closed ring shape that may be formed into a 1-D array.

Each of the hexagons of the CR-VCSEL 1-D array 500 of FIG. 5 are bounded by an inner trench 518 in a closed ring configuration and an outer trench 520 in a closed ring configuration. Adjoining trenches 521 form the trenches between adjacent hexagons. The space between the adjoining trenches 521 is the same as the space between the inner trench 518 and the outer trench 520, allowing the formation of an emission aperture 534 confining the optical modes 536 to a single optical mode for the in the transverse direction for all hexagon segments and multiple optical modes 536 around the hexagons.

Each hexagon of the CR-VCSEL 1-D array 500 contains oxidized regions 532 of an oxidation layer 110 (referred to in FIG. 1B) adjacent to the inner trench 518, the outer trench 520, and adjoining trenches 521 which form from an oxidation of the oxidation layer (not specifically shown). The region of the oxidation layer 110 shown in FIG. 1E which remains unoxidized after the oxidation process is shown in FIG. 1E is the emission aperture 134 and corresponds in FIG. 5 and is the emission aperture 534.

During operation of the CR-VCSEL 1-D array 500, optical modes 536 form in the active region (not specifically shown) under the emission aperture 534 of the closed ring hexagons of the CR-VCSEL 1-D array 500. The optical modes 536 under the emission aperture 534 are in physical proximity to each other such that the electric field of the plurality of optical modes 536 around the closed ring of the hexagons influence one another with the plurality of optical modes 536 locking together to form a single “supermode” at a single wavelength. Sharing of the optical modes 536 in the CR-VCSEL 1-D array 500 occurs between adjoining trenches 521 of adjoining hexagons of the CR-VCSEL 1-D array 500.

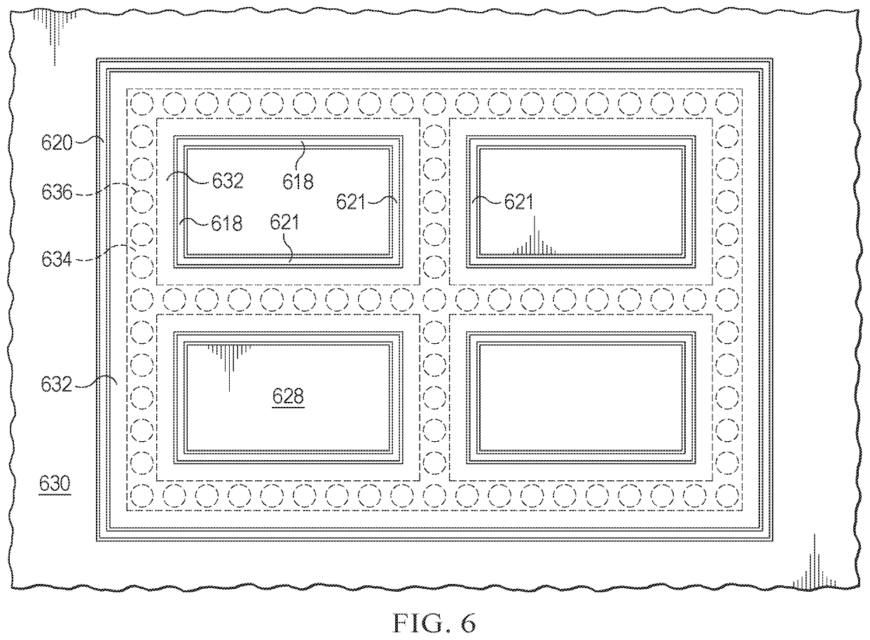

FIG. 6 is a top-down representation CR-VCSEL 2-D array 600. The CR-VCSEL 2-D array 600 shown in FIG. 6 consists of rectangles, but could be formed of any closed ring which may be tiled in in a 2-D array. The CR-VCSEL 2-D array 600 of FIG. 6 is formed in a manner similar to the oxide trench CR-VCSEL 100 referred to in FIGS. 1A-1G. The CR-VCSEL 2-D array 600 may also be formed with a in a manner similar to the back emitting oxide trench CR-VCSEL 200, the top ridge emitting CR-VCSEL 300 or the buried index guide CR-VCSEL 400 by way of example.

Each cell of the CR-VCSEL 2-D array 600 of FIG. 6 is bounded by an inner trench 618 in a rectangular closed ring configuration. An outer trench 620 in a rectangular closed ring configuration surrounds the CR-VCSEL 2-D array 600. An adjoining trench 621 is located between adjacent rectangles. The space between adjoining trenches 621 is the same as the space between the inner trench 618 and the outer trench 620, the width of adjoining trenches 621, the inner trench 618, and the outer trench 620, all forming an emission aperture 634 width which confines the optical modes 636 to a single optical mode in the transverse direction and allows multiple optical modes 636 around all close ring of each rectangle in the CR-VCSEL 2-D array 600. The uniformity of distances between the inner trench 618 to the outer trench 620 and between the adjoining trenches 621 of adjacent cells of the array allow for a uniform width of the emission aperture 634 throughout the 2-D array.

During operation of the CRVCSEL 2-D array 600, optical modes 636 form in the active region under the emission aperture 634. The optical modes 636 under the emission aperture 634 are in physical proximity to each other such that the electric field of the plurality of optical modes 636 in the closed ring influence one another with the plurality of optical modes 636 locking together to form a single “supermode” at a single wavelength throughout the CR-VCSEL 2-D array 600.

A CR-VCSEL individually addressable 2-D array may also be formed (not specifically shown). In a CR-VCSEL individually addressable 2-D array, the adjoining trenches 621 are removed and replaced with an inner trench 618 and an outer trench 620 for between each cell of the addressable 2-D array. The top metal layer and bottom metal layer of each cell of the addressable 2-D array is electrically isolated from the other cells in the addressable 2-D array, with the top metal layer and bottom metal layer for each cell in electrical contact with addressing circuitry such that each cell is individually addressable. Whether addressed individually or electrically connected in common, no “supermode” including all the cells is created, but other desirable emission properties of CR-VCSEL's are still available.

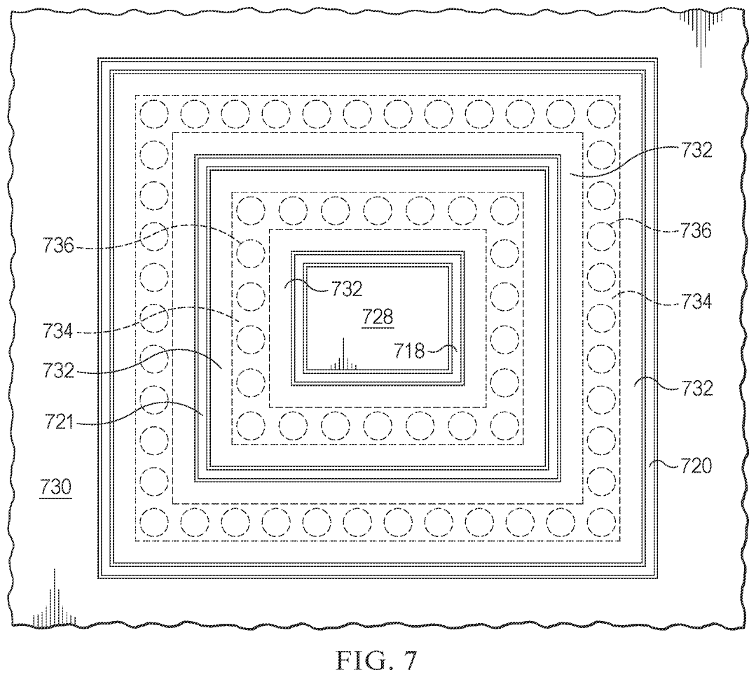

FIG. 7 is a top-down representation of a nested CR-VCSEL 700. The nested CR-VCSEL 700 shown in FIG. 7 consists of two closed ring emission apertures 734 which are in a nested configuration. A nested CR-VCSEL 700 with more than two closed ring emission apertures 734 is within the scope of the disclosure. In FIG. 7, the nested CR-VCSEL 700 is square, but other closed ring shapes which can be nested are within the scope of the disclosure. The nested CR-VCSEL 700 of FIG. 7 is formed in a manner similar to the oxide trench CR-VCSEL 100 referred to in FIGS. 1A-1G. The nested CR-VCSEL 700 may also be formed with a structure similar to the back emitting oxide trench CR-VCSEL 200, the top ridge emitting CR-VCSEL 300 or the buried index guide CR-VCSEL 400 by way of example.

The nested CR-VCSEL 700 of FIG. 7 is bounded by an inner trench 718 in a closed ring configuration and an outer trench 720 in a closed ring configuration. Approximately equidistant between the inner trench 718 and the outer trench 720, a middle trench 721 is formed. The approximately equal spacing of the inner trench 718, the middle trench 721, and the outer trench 720 allows the oxidation step (referred to in FIG. 1E to form oxidation regions 732 of the same width, and thus nested emission apertures 734 of the same width.

During operation of the nested CR-VCSEL 700, optical modes 736 form in the active region (not specifically shown) under the emission aperture 734. The width of the emission aperture 734 between the inner trench 718, the middle trench 721 and the outer trench 720 allow a single optical mode in the transverse direction between the inner trench 718 and the middle trench 721 for the inner nested ring, and another single optical mode in the transverse direction between the middle trench 721 and the outer trench 720, and multiple optical modes around the both nested closed rings of the nested CR-VCSEL 700. The optical modes 736 under the emission aperture 734 around the closed rings of the nested CR-VCSEL 700 may be in physical proximity to each other such that the electric field of the plurality of optical modes 736 influence one another with the plurality of optical modes 736 locking together to form a single “supermode” at a single wavelength under the emission aperture 734 of the nested CR-VCSEL 700. Nested CR-VCSEL's with spacings between inner trench 721 and outer trench 720 large enough that no “supermode” is formed are also possible, with the option of operating inner and outer emission regions 734 either individually or together.

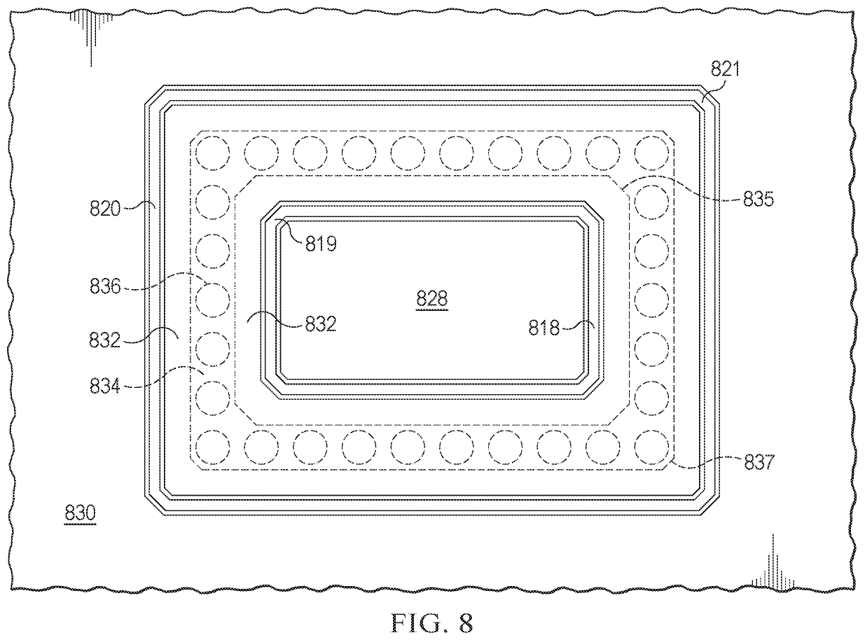

FIG. 8 is a top-down representation of a clipped corner CR-VCSEL 800. The clipped corner CR-VCSEL 800 shown in FIG. 8 is rectangular in shape, but could be formed of any closed ring shape which may be configured with a clipped corner 821. A clipped corner 821 consists of a corner in which either straight segments (shown) or rounded segments (not specifically shown) are used to join the corners of the clipped corner CR-VCSEL 800 such that all corners either have an obtuse (greater than 90 degree) overall corner geometry or a rounded geometry. It may be advantageous to the functionality of the clipped corner CR-VCSEL 800 to have one or more clipped corners 821. The clipped corner CR-VCSEL 800 of FIG. 8 is formed in a manner similar to the oxide trench CR-VCSEL 100 referred to in FIGS. 1A-1G. The clipped corner CR-VCSEL 800 may also be formed with a structure similar to the back emitting oxide trench CR-VCSEL 200, the top ridge emitting CR-VCSEL 300 or the buried index guide CR-VCSEL 400 by way of example. The clipped corner CR-VCSEL 800 of FIG. 8 is bounded by an inner trench 818 and an outer trench 820 in a closed ring configuration. At each corner of the inner trench 618 and the outer trench 820, a clipped corner 821 structure is used. The clipped corner 821 consists of a corner of the inner trench 818 and outer trench 820 in which either straight segments (shown) or curved segments (not specifically shown) are used to join the edges of the clipped corner CR-VCSEL 800 to ensure any corners of the clipped corner CR-VCSEL 800 have an obtuse (greater than 90 degree) or curved overall corner geometry.

While various examples of the present disclosure have been described above, it should be understood that they have been presented by way of example only and not limitation. As such, although foregoing examples are described to use various resist layers (e.g., photoresist or photomask layers) to perform various process steps (e.g., implant steps or etch steps), the present disclosure is not limited thereto. For example, one or more hard masks (including one or more layers) may be patterned to define various regions for subsequent process steps to be applied (e.g., regions for receiving dopant atoms, regions to block etchants). Moreover, the resist layers may include multi-level resists instead of a single-level resist in some examples. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the following claims and their equivalents.

What is claimed is:

1. A Coherent Ring Vertical Cavity Surface Emitting Laser (CR-VCSEL) comprising:
a substrate;
a bottom metal layer in electrical contact with a bottom surface of an active layer;
a CR-VCSEL stack on the substrate, the CR-VCSEL stack being a closed ring, the CR-VCSEL stack comprising;
a first mirror layer;
an active layer on the first mirror layer;
an emission aperture with a single optical mode transverse to the closed ring;
a second mirror layer above the active layer; and
a top metal layer on the second mirror layer, the top metal layer being in electrical contact with the top surface of the active layer, wherein the emission aperture is between the bottom metal layer and the top metal layer;
a first terminal in electrical contact with the bottom metal layer; and
a second terminal in electrical contact with the top metal layer.

2. The CR-VCSEL of claim 1, wherein an inner trench and an outer trench, the inner trench and the outer trench being closed rings, extend from a top surface of the second mirror layer into the first mirror layer and are on opposite sides of the emission aperture.

3. The CR-VCSEL of claim 2, wherein any corners of the inner trench and the outer trench at the top surface of the second mirror layer are obtuse angles.

4. The CR-VCSEL of claim 2, wherein any corners of the inner trench and the outer trench at the top surface of the second mirror layer are curved.

5. The CR-VCSEL of claim 1, wherein the CR-VCSEL stack is in a back emitting configuration, a laser configured to emit from the substrate of the CR-VCSEL, the substrate being free of the bottom metal layer under the emission aperture.

6. The CR-VCSEL of claim 1, wherein the CR-VCSEL stack is a top ridge emitting configuration, the second mirror layer and the emission aperture being of an approximately same width.

7. The CR-VCSEL of claim 1, wherein the CR-VCSEL stack is a buried index guide configuration.

8. The CR-VCSEL of claim 1, wherein one or more oxidation layers are between a bottom surface of the first mirror layer and a top surface of the second mirror layer.

9. The CR-VCSEL of claim 1, wherein the top metal layer comprises a first metal ring and a second metal ring on the second mirror layer, the first metal ring and the second metal ring being closed rings on opposite sides of the emission aperture.

10. The CR-VCSEL of claim 1, wherein a plurality of CR-VCSEL cells are in an array, the top metal layer of the plurality of CR-VCSEL cells being in electrical contact with the second terminal, the bottom metal layer of the plurality of CR-VCSEL cells being in electrical contact with the first terminal, with adjoining CR-VCSEL cells of the array sharing optical modes.

11. The CR-VCSEL of claim 1, wherein a plurality of CR-VCSEL cells are in an array, the top metal layer of the plurality of CR-VCSEL cells being in electrical contact with the second terminal, the bottom metal layer of the plurality of CR-VCSEL cells being in electrical contact with the first terminal.

12. The CR-VCSEL of claim 1, wherein a plurality of CR-VCSEL cells are in an array, each of the plurality of CR-VCSEL cells being individually addressable.

13. The CR-VCSEL of claim 1, wherein a plurality of CR-VCSEL cells are in a nested configuration.

14. A method of forming a Coherent Ring Vertical Cavity Surface Emitting Laser (CR-VCSEL) comprising:
forming a CR-VCSEL stack on a substrate, the CR-VCSEL stack being a closed ring, the CR-VCSEL stack being formed by a method including;
forming a first mirror layer;
forming an active layer on the first mirror layer;
forming an emission aperture with a single optical mode transverse to the closed ring;
forming a second mirror layer above the active layer; and
forming a top metal layer on the second mirror layer, the top metal layer in electrical contact with a bottom surface of the active layer;
forming a bottom metal layer in electrical contact with a bottom surface of the active layer;
forming a first terminal in electrical contact with the bottom metal layer; and
forming a second terminal in electrical contact with the top metal layer.

15. The method of claim 14, wherein forming the emission aperture includes forming one or more oxidation layer above a bottom surface of the first mirror layer and below a top surface of the second mirror layer.

16. The method of claim 14, comprising forming a first trench and a second trench extending from a top surface of the second mirror layer into the first mirror layer and intersecting an oxidation layer, the first trench and the second trench being closed rings on opposite sides of the emission aperture.

17. The method of claim 16, comprising oxidation of a portion of an oxidation layer between the first trench and the second trench, forming the emission aperture.

18. The method of claim 14, comprising forming the CR-VCSEL stack wherein the second mirror layer, the active layer and the emission aperture are approximately equal in width.

19. The method of claim 14, comprising forming the top metal layer including a first metal ring and a second metal ring on the second mirror layer, the first metal ring and the second metal ring being closed rings on opposite sides of the emission aperture.

20. The method of claim 14, comprising forming the CR-VCSEL stack in a back emitting configuration and the substrate being free of the bottom metal layer under the emission aperture.
